(19) United States
(12) Patent Application Publication
(10) Pub. No.: US 2026/0362634 A1
(43) Pub. Date: Nov. 12, 2026

(54) APPLIANCE IMMERSION COOLING SYSTEM

(71) Applicant: Midas Green Technology, LLC, Austin, TX (US)

(72) Inventor: Christopher L. Boyd, Austin, TX (US)

(21) Appl. No.: 19/747,290

(22) Filed: Jul. 20, 2026

Related U.S. Application Data
(63) Continuation of application No. 19/268,301, filed on Jul. 14, 2025.
Application No. 19/268,301 is a continuation of application No. 17/035,343, filed on Sep. 28, 2020, now Pat. No. 12,402,271.
Application No. 17/035,343 is a continuation of application No. 16/243,732, filed on Jan. 9, 2019, now Pat. No. 10,820,446.
Application No. 16/243,732 is a continuation of application No. 14/355,533, filed on Apr. 30, 2014, now Pat. No. 10,405,457.
Application No. 14/355,533 is a continuation of application No. PCT/US13/75126, filed on Dec. 13, 2013.
(60) Provisional application No. 61/737,200, filed on Dec. 14, 2012.
(60) Provisional application No. 61/832,211, filed on Jun. 7, 2013.

(51) Int. Cl. H05K 7/20

(52) U.S. Cl. CPC H05K 7/20236; H05K 7/20272; H05K 7/20281; H05K 7/20936

(57) ABSTRACT

An appliance immersion tank system comprising: a generally rectangular tank adapted to immerse in a dielectric fluid a plurality of appliances, each in a respective appliance slot distributed vertically along, and extending transverse to, the long axis of the tank; a primary circulation facility adapted to circulate the dielectric fluid through the tank; a secondary fluid circulation facility adapted to extract heat from the dielectric fluid circulating in the primary circulation facility, and to dissipate to the environment the heat so extracted; and a control facility adapted to coordinate the operation of the primary and secondary fluid circulation facilities as a function of the temperature of the dielectric fluid in the tank. A plenum, positioned adjacent the bottom of the tank, is adapted to dispense the dielectric fluid substantially uniformly upwardly through each appliance slot. A weir, integrated horizontally into a long wall of the tank, is adapted to facilitate substantially uniform recovery of the dielectric fluid flowing through each appliance slot. All active and most passive components of both the primary and secondary fluid circulation facilities, and the control facility are fully redundant, and are adapted automatically to operate in a fail-soft mode.

### PRIORITY CLAIM

This application is a continuation application of U.S. patent application Ser. No. 19/268,301, filed Jul. 14, 2025, titled “APPLIANCE IMMERSION COOLING SYSTEM,” which is a continuation application of U.S. patent application Ser. No. 17/035,343, filed Sep. 28, 2020, titled “APPLIANCE IMMERSION COOLING SYSTEM,” which issued as U.S. Pat. No. 12,402,271, which is a continuation application of U.S. patent application Ser. No. 16/243,732, filed Jan. 9, 2019, titled “APPLIANCE IMMERSION COOLING SYSTEM,” which issued as U.S. Pat. No. 10,820,446, which is a continuation application of U.S. patent application Ser. No. 14/355,533, filed Apr. 30, 2014, titled “APPLIANCE IMMERSION COOLING SYSTEM,” which issued as U.S. Pat. No. 10,405,457, which is a continuation application of U.S. National Stage Application No. PCT/US 13/75126, filed Dec. 13, 2013, titled “APPLIANCE IMMERSION COOLING SYSTEM,” which claims priority to U.S. Provisional Patent Application Nos. 61/737,200, titled “SERVER IMMERSION TANK SYSTEM,” filed Dec. 14, 2012, and 61/832,211, titled “SERVER IMMERSION TANK SYSTEM,” filed Jun. 7, 2013. The provisional applications are incorporated by reference herein in their entirety.

### BACKGROUND

The present invention relates generally to electrical appliance cooling systems, and, in particular, to an improved appliance immersion cooling system and method of operation.

### Description of the Related Art

In general, in the descriptions that follow, we will italicize the first occurrence of each special term of art which should be familiar to those skilled in the art of immersion cooling systems. In addition, when we first introduce a term that we believe to be new or that we will use in a context that we believe to be new, we will bold the term and provide the definition that we intend to apply to that term.

U.S. Pat. No. 4,590,538, “Immersion Cooled High Density Electronic Assembly”, Cray (filed 18 Nov. 1981 and issued 20 May 1986) (“Cray”), is an early example of an immersion system for cooling electronic components during normal operation. On information and belief, the machine disclosed therein was the Cray-2 super-computer (“Cray-2”) manufactured by Cray Research, Inc. (“Cray Research”), of Chippewa Falls, Wisconsin. Of particular interest to the present application is the description of the significant advantages resulting from using an electrically non-conductive or dielectric fluid to extract heat from electronic circuit assemblies during normal operation (see, e.g., col. 1, line 66-col. 2, line 29).

On information and belief, Cray Research released, in 1985, a marketing brochure entitled “The CRAY-2 Computer System” (a copy of which is submitted herewith) describing the Cray-2. Of particular interest in this brochure is the description therein of the significant advantages resulting from using a dielectric fluid to extract heat from electronic circuit assemblies during normal operation (see, pages 10 and 13).

U.S. Pat. No. 5,167,511, “High Density Interconnect Apparatus”, Krajewski, et al. (issued 27 Nov. 1992) (“Krajewski”), discloses another example of an immersion system for cooling electronic components during normal operation (see, e.g., col. 2, lines 43-51). On information and belief, a machine implementing the Krajewski system was also marketed by Cray Research as a follow-on super-computer to the Cray-2.

One particular problem in the vertical-stack-type systems disclosed in the above references is the necessity of draining the cooling fluid whenever physical access to the electronic modules was required. In general, such an operation, besides being time consuming, requires the entire system to be switched off, especially if the component requiring attention is an essential element in the system architecture, such as the central processing unit (“CPU”). One possible solution to this problem is to immerse circuit assemblies vertically into a tank containing the cooling fluid such that each of the various assemblies can be withdrawn independently from the tank for servicing, replacement, upgrade, etc. One interesting example of such a system is disclosed in a web-presentation entitled “Puget Custom Computer's mineral-oil-cooled PC”, by Nilay Patel (“Puget”) (posted 12 May 2007 at 11:57AM; a copy of which is submitted herewith). As noted by the author, the lack of supplemental apparatus in the Puget system to extract waste heat from the oil inherently limited its operating capabilities.

Another problem with the Cray Research systems in particular is the nature and cost of the chosen cooling fluid: fluorocarbon liquids. As is known, other dielectric fluids, such as mineral oil, have better heat transfer characteristics; of course, being an oil, the use thereof does represent a greater residue problem on modules that may be repairable. Notwithstanding, the Puget system implemented precisely this design choice.

US Patent Application Publication 2011/0132579, “Liquid Submerged, Horizontal Computer Appliance Rack and Systems and Method of Cooling such a Appliance Rack”, Best, et al. (“Best”), discloses an appliance immersion tank system, include support apparatus for extracting waste heat from the tank cooling fluid and dissipating to the environment the heat so extracted. Although an improvement in several respects over the prior art discussed above, this system exhibits, inter alia, the following problems: generally non-uniform flow patterns through the several appliance slots within the tank, potentially resulting in uneven cooling across all slots; constricted dielectric fluid supply and return ports resulting in unnecessarily high fluid flow velocities at the respective points of connection to the tank; poor scalability; and inadequate attention to fail-soft operation.

The subject matter of all of the prior art references discussed above, each in its entirety, is expressly incorporated herein by reference.

We submit that what is needed is an improved appliance tank immersion system and method of operation. In particular, we submit that such a system should provide performance generally comparable to the best prior art techniques but more efficiently and effectively than known implementations of such prior art techniques.

### SUMMARY

In one aspect, the present invention is directed to An appliance immersion cooling system comprising: a tank adapted to immerse in a dielectric fluid a plurality of electrical appliances, each in a respective appliance slot distributed vertically along, and extending transverse to, a selected wall of the tank; a primary circulation facility adapted to circulate the dielectric fluid through the tank, comprising: a plenum, positioned adjacent the bottom of the tank, adapted to dispense the dielectric fluid substantially uniformly upwardly through each appliance slot; a secondary fluid circulation facility adapted to extract heat from the dielectric fluid circulating in the primary circulation facility, and to dissipate to the environment the heat so extracted; and a control facility adapted to coordinate the operation of the primary and secondary fluid circulation facilities as a function of the temperature of the dielectric fluid in the tank.

### BRIEF DESCRIPTION OF THE DRAWINGS

Our invention may be more fully understood by a description of certain preferred embodiments in conjunction with the attached drawings in which:

FIG. 1 illustrates, in partial cut-away form, a front perspective of a tank module of an appliance immersion cooling system constructed in accordance with our invention;

FIG. 2 illustrates a rear perspective of the tank module shown in FIG. 1;

FIG. 3 illustrates a close-up perspective of a detail A of FIG. 2;

FIG. 4 illustrates a close-up perspective of a detail B of FIG. 2;

FIG. 5 illustrates, in perspective view, several details of the tank shown in FIG. 1, with special emphasis on the dielectric fluid recovery weir integrated into the long rear wall of the tank;

FIG. 6 illustrates, in cross-section view, the section C-C in FIG. 5;

FIG. 7 illustrates, in perspective view, the plenum facility shown in FIG. 1;

FIG. 8 illustrates, in top plan view, the orifice plate portion of the plenum facility shown in FIG. 7;

FIG. 9 illustrates, in perspective view, the chamber portion of the plenum facility shown in FIG. 7;

FIG. 10 illustrates, m top plan view, a plurality of appliance slots distributed vertically along, and extending transverse to, a long axis of the tank of FIG. 1;

FIG. 11 illustrates, in longitudinal cross-sectional view, the plurality of appliance slots distributed vertically along, and extending transverse to, the long axis of the tank of FIG. 1;

FIG. 12 illustrates, in flow schematic form, one instantiation of a flow arrangement suitable for implementing our invention; and

FIG. 13 illustrates, in control schematic form, one instantiation of a flow control facility suitable for implementing our invention.

In the drawings, similar elements will be similarly numbered whenever possible. However, this practice is simply for convenience of reference and to avoid unnecessary proliferation of numbers, and is not intended to imply or suggest that our invention requires identity in either function or structure in the several embodiments.

### DETAILED DESCRIPTION

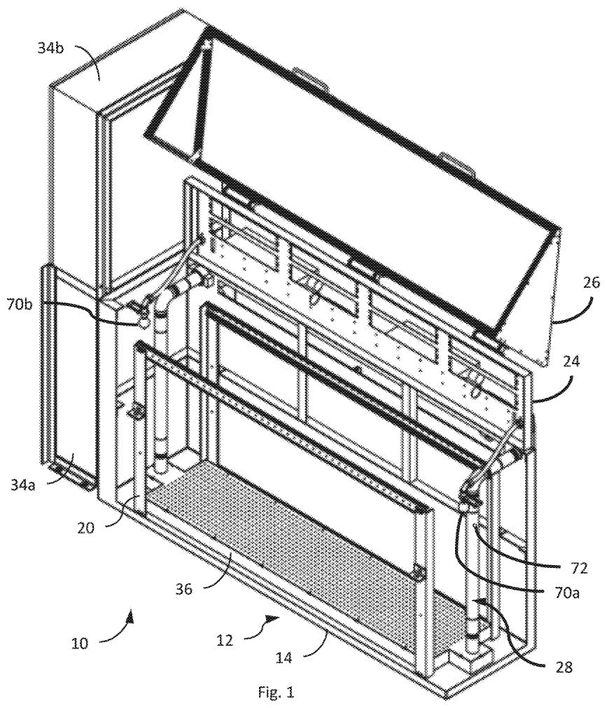

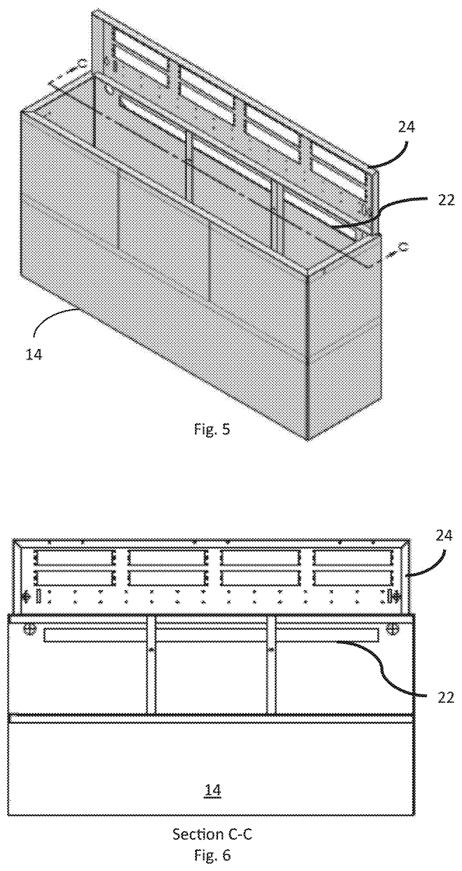

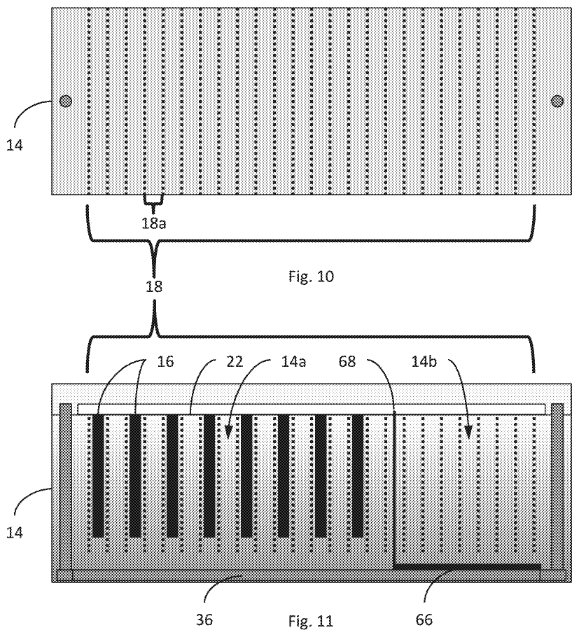

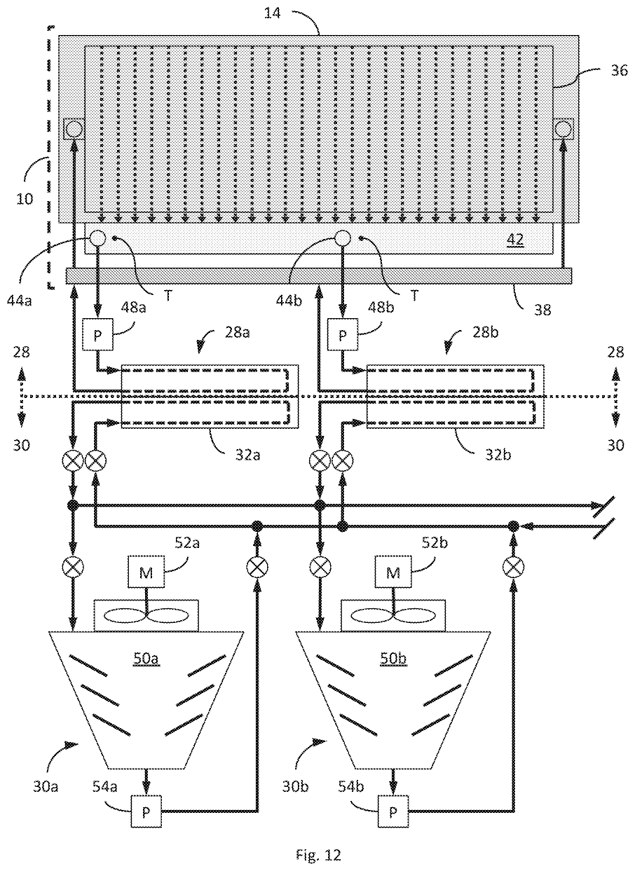

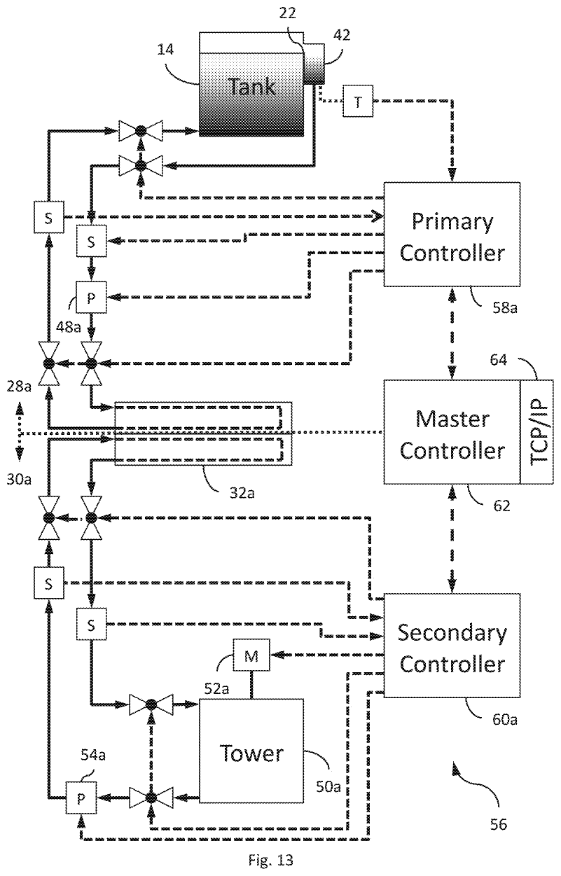

Shown in FIG. 1 (front view) and FIG. 2 (rear view) is a tank module 10 adapted for use in an appliance immersion cooling system constructed in accordance with a preferred embodiment of our invention. For convenience of reference, we have illustrated in FIG. 1 the tank facility 12 of the immersion module 10 in partial cut-away to emphasize several important internal facilities; we have shown the tank facility 12 in isolation in FIG. 5. In general, the tank facility 12 comprises: a tank 14 adapted to immerse in a dielectric fluid a plurality of electrical appliances 16, e.g., contemporary computer servers (see, e.g., FIG. 11), each in a respective appliance slot 18a distributed vertically along, and extending transverse to, a long axis of the tank 14 (see, generally, FIG. 10); an appliance rack facility 20 of convention design adapted to suspend the appliances 16 (see, e.g., FIG. 11) in respective appliance slots 18 (see, FIG. 10); a weir 22 (best seen in isolation in FIG. 5 and FIG. 6), integrated horizontally into one long wall of the tank 14 adjacent all appliance slots 18, and adapted to facilitate substantially uniform recovery of the dielectric fluid flowing through each of the appliance slots 18; an interconnect panel facility 24 attached to the upper rear edge of the tank 14 and adapted to mount various appliance power distribution equipment, cable interconnection panels and the like (none shown); and a cover 26 adapted to be opened and closed from the front of the tank 14 (and which may include a translucent portion to allow viewing of the interior of the tank 14 when in the closed position). In addition to the tank facility 12, the immersion module 10 comprises: a primary circulation facility 28 (portions of which are shown in both FIG. 1 and FIG. 2); a secondary fluid circulation facility 30 (of which only redundant heat exchangers 32a and 32b are shown in FIG. 2); and control equipment cabinets 34a and 34b, each adapted to accommodate the module status and control equipment associated with a respective one of the primary circulation facilities 28a and 28b (see, FIG. 13).

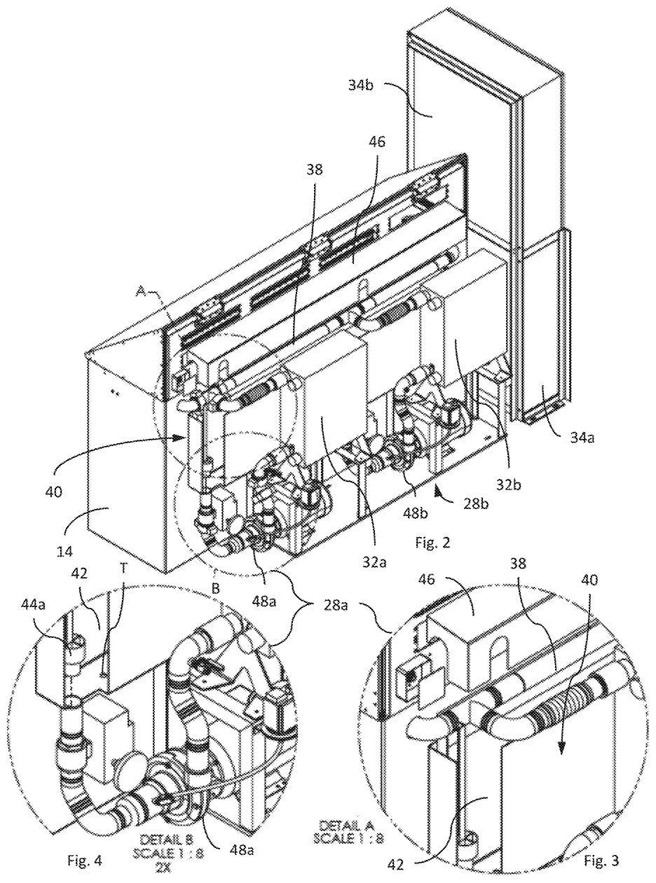

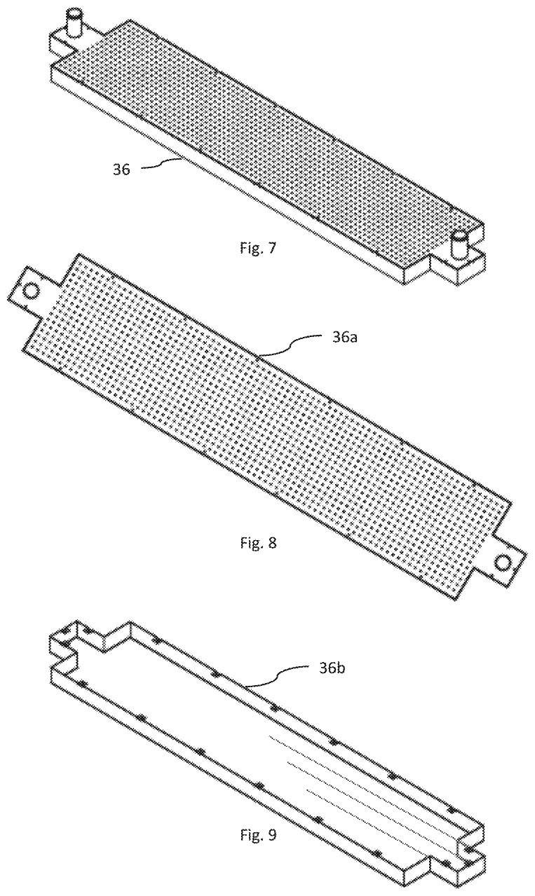

As can be best seen in FIG. 2, the primary circulation facility 28 (comprising redundant sub-facilities 28a and 28b) comprises both passive (conduits, couplers, etc.) and active (valves, pumps, sensors, etc.) components; a subset of the passive components are shared, whereas, in general, the active components are duplicated and adapted to cooperate in operation as separate, redundant sub-facilities. Excluding the tank 14, the primary shared component is the plenum facility 36 (see, FIG. 1 and FIG. 7) comprising an orifice plate 36a (see, FIG. 8) and a plenum chamber 36b (see, FIG. 9). As can be seen in FIG. 1, cooled dielectric fluid is pumped into both ends of the plenum facility 36 via a shared distribution header 38 (see, FIG. 2 and FIG. 3). In general, the plenum plate 36a comprises at least one row of orifices vertically aligned with each appliance slot 18a, with the dimensions and flow rates of each set being adapted to provide substantially equal flow of the dielectric fluid upwardly into each appliance slot 18a. Preferably, each appliance slot 18a is supplied via several rows of orifices, thus generally tending to reduce the volume of the dielectric fluid exiting each orifice and to make the flow of dielectric fluid more uniform upwardly through the appliance slots 18. One further shared component is the dielectric fluid recovery facility 40 (FIG. 2) comprising a dielectric fluid recovery reservoir 42 (see, FIG. 3, FIG. 4 and FIG. 13) positioned vertically beneath the overflow lip of the weir 22 and adapted smoothly to receive the dielectric fluid as it flows over the weir 22; the dielectric fluid recovery reservoir 42 is further adapted to allow the recovered fluid to be removed from the reservoir 42 via redundant recovery ports 44a and 44b (only port 44a can be seen in FIG. 2 as the port 44b is obscured by the heat exchanger 32a; but see FIG. 12). As can be seen in both FIG. 3 and FIG. 4, we consider it desirable to provide a vortex breaker at the input of each of the recovery ports 44. Also, we provide a removable recovery reservoir cover 46 adapted to also cover a major portion of the distribution header 38; note that, in both FIG. 2 and FIG. 3, we have illustrated the reservoir cover 46 in a partially raised orientation so as to better depict details that would otherwise be obscured. Note that we have constructed the reservoir 42 such that the average height of dielectric fluid above the recovery ports 44 develops sufficient hydrostatic head to meet the requirements of the pumps 48, while also tending to minimize the likelihood of breaking suction during normal operation.

At this point in the primary circulation facility 28, we provide fully redundant sub-facilities 28a and 28b, each comprising a primary circulation pump (48a and 48b) and associated passive and active components which, collectively, provide the motive power for circulating the dielectric fluid through the shared components and tank 14. As can be generally seen, each of these sub-facilities 28a and 28b is adapted to recover the dielectric fluid exiting the tank 14 via the weir 22, re-pressurize the recovered fluid, pass the re-pressurized fluid through a respective one of the heat exchangers 32a and 32b, and then back to the plenum facility 36 via the header 38.

Shown in FIG. 12 is one flow arrangement suitable for integrating our tank module 10 into a fully redundant, appliance immersion cooling system, comprising the primary circulation facility 28 and the secondary fluid circulation facility 30. In general, the secondary fluid circulation facility 30 comprises redundant secondary circulation sub-facilities 30a and 30b, each of which is adapted to circulate a cooling fluid, e.g., treated water, through the respective heat exchanger 32a and 32b to extract heat from dielectric fluid counter-circulating therethrough and to dissipate to the environment the heat so extracted. In the illustrated embodiment, each of the secondary fluid sub-facilities 30a and 30b comprise conventional cooling towers 50a (including fan facility 52a) and 50b (including fan facility 52b), and secondary circulation pumps 54a and 54b. To facilitate flexible operation in installations including multiple immersion modules 10 in combination with a plurality of secondary circulation sub-facilities 30, a common header arrangement can be implemented as illustrated in the secondary fluid circulation loop, with flow control valves located at key flow control points as is known.

Shown in FIG. 13 is a control facility 56 adapted to monitor and control the operation of both the immersion module 10 (including all active components of the primary circulation facility 28), and the secondary fluid circulation facility 30. As will be evident to those skilled in this art, efficient operation of our immersion module 10 requires continuous monitoring and control of several essential operating parameters, including fluidic temperatures, pressures, conductivity and pH at several points in the primary and secondary circulation loops. Although the several sensory and control functions can be implemented using traditional dedicated hardware components, we prefer to employ at least one programmable logic controller (“PLC”), commercially available from any of a number of respected vendors, e.g., the Allen-Bradley brand of PLCs from Rockwell Automation, Inc. In the instantiation illustrated in FIG. 13, we have depicted: a primary controller 58a adapted to monitor and control the operation of the primary circulation sub-facility 28a as a function of the temperature of the dielectric fluid in the tank 14; a secondary controller 60a adapted to monitor and control the operation of the secondary fluid circulation sub-facility 30a as a function of the temperature of the dielectric fluid flowing through the heat exchanger 32a; and a master controller 62 adapted to coordinate the activities of the primary controller 58a and secondary controller 60a. As can be seen, we have incorporated into the primary circulation sub-facility 28a: supply and return sensors, including a temperature probe, T, inserted into a thermowell (not shown) installed in the bottom of the reservoir 42 adjacent a respective return port 44a (note that, in FIG. 4, only one of the holes that receive the thermowells is illustrated, but both holes are illustrated in FIG. 12); a pair of sensor facilities, S, which may sense temperature, pressure and conductivity, as deemed desirable); and return (and, if desired, supply) flow control valves and controls for the primary circulation pump 48a; of course, a redundant set of these components exists for the primary circulation sub-facility 28b. In general, the goal is to maintain the temperature of the dielectric fluid in the tank 14 between a predetermined mm 1 mum temperature and a predetermined maximum temperature.

As noted above, we have provided separate control equipment cabinets 34a and 34b, each adapted to accommodate the several components comprising a respective one of the primary controllers 58a and 58b. For convenience of access, we prefer to co-locate with each of the cooling towers 50 a protective housing (not shown) for the respective secondary controller 60. Of course, the control facility 56 can be instantiated as a single, multi-module PLC facility, with similar or other combinations of monitoring devices as deemed most appropriate for a particular installation. Alternatively, one or more, and perhaps all, of the functions performed by the controllers 58, 60 and 62 may be implemented in the form of dedicated application-specific software executing on a conventional computer platform having the appropriate resources; indeed, it would be entirely feasible to implement the entire control facility 56 on a server 16 installed in a tank 14.

One desirable enhancement that we recommend is a remote control facility, implemented, e.g., via the master controller 62 (or by way of a direct, per-controller interface), adapted to facilitate remote monitoring of system status (e.g., temperatures, pressures, etc.) and control over system control parameters (e.g., temperature and pressure limits, etc.) to the primary controllers 58 and secondary controllers 60. For example, using a conventional data communication hardware module 64, e.g., an ethernet card implementing the TCP/IP protocol, a modern web browser can be adapted to provide a graphical user interface (“GUI”) with sufficient functionality to facilitate monitoring and control of an entire installation from a remote location. Such a GUI may be implemented using any of a number of programming paradigms, e.g., PHP, . NET and the like.

Operational control of redundant, continuous process flow systems is generally well known. Preferably, each of the several redundant sub-facilities are routinely activated to assure current functionality, and to allow the inactive sub-facility to be serviced according to an established schedule. We believe this continuous rotation of system resources to be so important that we recommend switching the sub-facilities at least once, and preferably, several times, per day; although this is possible to implement manually, we prefer to enable the master controller 62 to control the sequencing of the several switch-over operations. One further aspect of this sophistication in control is the ability to perform stress testing of the several sub-systems under controlled conditions so as to assure appropriate response to real-time emergencies.

In our First Parent Provisional, we have disclosed an alternate embodiment comprising an appliance immersion tank facility wherein the function of the plenum facility 36 is performed by a manifold facility comprising a ladder-arrangement of tubular spray bars, each bar of which supplies dielectric fluid to a respective appliance slot. As we noted, one particular advantage of this arrangement is that individual spray bars may be shut off if the respective appliance slot is not occupied and, thus, save energy. To further increase energy efficiency, we have provided optional vertical flow barriers adapted to partition the tank into an active portion, having active appliances, and a stagnant portion, having no active appliances. One further enhancement we disclosed is the provision of temperature sensors per appliance slot, such that the flow rate through each spray bar can be dynamically varied as a function of the temperature of the dielectric fluid exiting the respective slot. Other operative configurations will be readily perceived by those skilled in this art.

In a manner analogous to the embodiment described in our First Parent Provisional, it would be advantageous, from an energy point of view, to provide a plurality of flow barrier plates 66 (shown by way of example only in FIG. 11), each adapted to be attached to the top of the plenum facility 36 so as substantially to block the flow of the dielectric fluid through the row(s) of orifices in the plenum plate 36a corresponding to at least a respective one of the appliance slots 18a; an elastomeric layer (not shown) could be provided on the interface surface of the plate(s) 66 to enhance the sealing effect. Such an arrangement would allow the total flow through the plenum facility 36 to be adjusted, in the field, as a function of the actual number of active appliances 16 in the tank 14. Further, this arrangement can incorporate a relocatable vertical baffle plate 68 (see FIG. 11) adapted substantially to partition the tank 14 into an active portion 14a containing the active appliances 16 and an inactive portion 14b containing no appliances (or at least no active appliances 16); preferably, the baffle plate 68 is adapted to be mounted in the appliance rack facility 28 in a manner similar to an actual appliance 16 (the baffle plate 68 need not fully block the flow of dielectric fluid between the active portion 14a and inactive portion 14b, but only significantly impede the flow between these portions). Note that, in the example scenario illustrated in FIG. 11, we have shown one possible arrangement of a total of 8 active appliances 16 distributed across 16 appliance slots 18a so as to spread the total heat load across adjacent empty slots 18a. Such an optimal arrangement is possible only if less than a majority of the available appliance slots 18a are occupied by an active appliance 16. Clearly, such optional adjunct facilities enhance flexibility in operation, accommodating dynamic adjustment of the flow rates in the primary circulation sub-facilities 28a and 28b under variable heat loads, while providing opportunities to conserve energy that might otherwise be expended moving the dielectric fluid through the inactive portion 14b of the tank 14. Other operative configurations will be readily perceived by those skilled in this art.

In our Second Parent Provisional, we have disclosed another embodiment comprising a more conventional, less-modularized instantiation with appropriate flow and control facilities. In this embodiment, we chose to implement tank clusters, comprising, e.g., 4 appliance immersion tank facilities, with substantially all of the other equipment being constructed from stand-alone, commercially available components. Such an arrangement offers greater opportunities to select and install improved components, or to add enhancements to the installation, as deemed desirable after initial installation. Other operative configurations will be readily perceived by those skilled in this art.

As we noted above with reference to the embodiment illustrated in FIG. 12, the secondary flow header facility is well adapted to allow any secondary circulation sub-facility 30 to be connected to any active heat exchanger 32. Such a facility provides great flexibility in dealing with unusual system conditions, especially in installations wherein the secondary circulation sub-facilities 30a and 30b are each sized to support a cluster of tank modules 10. Imagine, for example, that, while one of the secondary circulation facilities 30, say sub-facility 30a, is being serviced, the activities of the set of appliances 16 in one tank 14 in the cluster are higher than normal, resulting in a rise in temperature in that tank 14 above the desired maximum. In response, the master controller 62 can direct Primary Controllers 58a and 58b, assigned to tank 14 to operate both of the primary circulation sub-facilities 28a and 28b simultaneously, i.e., in parallel. Using the secondary flow header facility, the heat being extracted by both of the heat exchangers 32a and 32b may be dissipated using the resources of the single on-line secondary circulation sub-facility 30b. Thus, one clear advantage of this alternate embodiment is the ability dynamically to perform load balancing across all system resources. Other operative configurations to support sub-system load balancing will be readily perceived by those skilled in this art.

Preferably, one or more filters (not shown) are included in the flow path through each of the primary circulation sub-facilities 28a and 28b to remove any particulates or other undesirable foreign matter that may have been picked up by the dielectric fluid on its passage through the entire primary circulation facility 28; chemical sensors may also be provided to detect the presence of unexpected chemicals that may indicate failure of sub-components within one of the appliances 16. Similar components, such as pH sensors, may also be included in the secondary fluid circulation facility 30.

As can be seen generally in FIG. 1, we provide a pair of low dielectric fluid level sensors 70a and 70b adapted to trigger an alarm signal in the event that, for whatever reason, the level of the dielectric fluid in the tank 14 drops below a predetermined minimum level. Additionally, the responsive primary controller 58 can initiate other actions to address the detected problem, including activating audio alarms, transmitting electronic alert signals and the like.

To solve a reciprocal problem, namely leakage from an external portion of the primary circulation loop 28 resulting in the dielectric fluid in the tank 14 being back-siphoned through the plenum facility 36, we recommend incorporating a siphon breaker 72 (see, FIG. 1) in the supply pipe at a predetermined location well above the plenum facility 36 but somewhat below the level of the weir 24. Such a siphon breaker can be as simple as a relatively small diameter hole 72 drilled through the supply pipe at the selected location; due to the relatively high viscosity of the dielectric fluid, even when heated, any resulting leakage during normal operation will be relatively insignificant. Other operative responses to address these and other unusual fluidic conditions will be readily perceived by those skilled in this art.

As is known (see, e.g., Best), many conventional, commercially available electrical/electronic appliances include components that will not function correctly if immersed in a dielectric fluid, especially one as viscous as mineral oil: cooling fans and rotating media disk drives. In general, all cooling fans are unnecessary in an immersion cooling system and can be simply removed. The media drives, however, are usually necessary for normal appliance operation. One option is to remove each drive, totally seal the drive against fluid entry, and reinstall the now-sealed drive (pre-sealed drives are also available). Another option is to remove the drive and mount it on the interconnect panel facility 24; typically special cabling will be required to re-attach the drive to the internal appliance socket. Yet another option is to replace the rotating media drive with a solid-state drive having no moving components. Other operative configurations will be readily perceived by those skilled in this art.

It will be recognized that, in all of the embodiments described herein, emphasis was placed on minimizing the total volume of the dielectric fluid circulating throughout each immersion module 10. We submit that the key concept here is to move the secondary fluid to the point of heat exchange with the primary fluid, rather than to move the primary fluid to the point of heat exchange with the secondary fluid. Thus, in our preferred embodiment, all of the essential components of the primary circulation facility 28 are tightly co-located with the tank 14 so as to form a highly-integrated module. Further, our placement of the reservoir 42 outside of (but immediately adjacent to) the tank 14 tends to reduce the total volume of the dielectric fluid (as opposed to the alternative arrangement we proposed in our First Provisional, wherein a recovery trough was disposed within the tank 14); then, we positioned the components comprising the primary circulation sub-facilities 28 so as to be vertically beneath the footprint of the reservoir 42. In addition to conserving valuable floor space in a typical data center installation, the resulting modular configuration facilitates both easy initial installation and subsequent upgrade to efficiently satisfy increasing data center workloads. Indeed, our invention greatly enhances system scalability, a key concern to data center operators. Finally, our system-wide redundancy substantially assures fail-soft operation during periods of unusual environmental conditions, infrastructure instability or political unrest.

Although we have described our invention in the context of particular embodiments, one of ordinary skill in this art will readily realize that many modifications may be made in such embodiments to adapt either to specific implementations. By way of example, it will take but little effort to adapt our invention for use with electronic appliances other than contemporary servers; and to adjust the dimensions of the appliance accommodation slots accordingly. Similarly, practitioners in the art will readily recognize that other, known secondary circulation facilities may be employed effectively, including forced air, vapor compression systems, earth-water sink loops, waste heat recovery and recycling systems, and the like (see, e.g., the several alternatives discussed in Best). Further, the several elements described above may be implemented using any of the various known manufacturing methodologies, and, in general, be adapted so as to be operable under either hardware or software control or some combination thereof, as is known in this art.

Thus it is apparent that we have provided an improved system and method of operation for immersion cooling of appliances and the like. In particular, we submit that such a method and apparatus provides performance generally comparable to the best prior art techniques but more efficiently and effectively than known implementations of such prior art techniques.

What is claimed is:

1. An immersion cooling system comprising:
a tank comprising a plurality of appliance slots, the tank configured to hold a dielectric fluid and a plurality of electrical appliances immersed in the dielectric fluid, each of the plurality of electrical appliances corresponding to a respective appliance slot of the plurality of appliance slots;
a weir comprising an overflow structure configured to facilitate substantially uniform recovery of the dielectric fluid from each of the plurality of appliance slots;
a fluid recovery reservoir configured to receive the dielectric fluid flowing from the overflow structure of the weir; and
a primary circulation facility comprising:
a plenum positioned adjacent to a bottom of the plurality of electrical appliances and configured to facilitate a flow of the dielectric fluid into each of the plurality of appliance slots; and
at least one primary circulation pump configured to pump the dielectric fluid from the fluid recovery reservoir to the plenum.

2. The immersion cooling system of claim 1, wherein the plenum comprises:
a plenum chamber; and
a plenum plate disposed on top of the plenum chamber, wherein the plenum plate comprising a plurality of orifices configured to facilitate the flow of the dielectric fluid from the plenum into the plurality of appliance slots.

3. The immersion cooling system of claim 2, wherein the plurality of orifices comprises at least one row of orifices aligned with each respective appliance slot of the plurality of appliance slots.

4. The immersion cooling system of claim 2, wherein the plurality of orifices comprise dimensions configured to provide a substantially equal flow rate of the dielectric fluid into each of the plurality of appliance slots.

5. The immersion cooling system of claim 2, further comprising a plurality of barrier plates configured to be removably attached to the plenum plate, each of the plurality of barrier plates configured to block the flow of the dielectric fluid through one or more orifices of the plurality of orifices corresponding to at least one of the plurality of appliance slots.

6. The immersion cooling system of claim 5, wherein an elastomeric layer is disposed on a surface of the plenum plate, the elastomeric layer configured to seal the plurality of barrier plates against the plenum plate.

7. The immersion cooling system of claim 1, wherein the at least one primary circulation pump comprises a first primary circulation pump and a second primary circulation pump, and wherein each of the first primary circulation pump and the second primary circulation pump are independently configured to pump the dielectric fluid from the fluid recovery reservoir to the plenum.

8. The immersion cooling system of claim 7, further comprising a control facility configured to selectively activate one or both of the first primary circulation pump and the second primary circulation pump as a function of a temperature of the dielectric fluid in the tank so as to maintain the temperature of the dielectric fluid within a predetermined temperature range.

9. The immersion cooling system of claim 1, further comprising:
a secondary circulation facility comprising a heat exchanger configured to extract heat from the dielectric fluid circulating through the primary circulation facility and to dissipate the extracted heat to the environment; and
a control facility configured to coordinate operation of the primary circulation facility and the secondary circulation facility as a function of a temperature of the dielectric fluid in the tank, to maintain the temperature of the dielectric fluid within a predetermined temperature range.

10. The immersion cooling system of claim 9, wherein the control facility is further configured to facilitate remote monitoring and control of operating parameters of the immersion cooling system via a communication network.

11. The immersion cooling system of claim 1, further comprising:
a secondary circulation facility comprising a heat exchanger configured to extract heat from the dielectric fluid circulating through the primary circulation facility and to dissipate the extracted heat to the environment; and
a control facility configured to coordinate operation of the primary circulation facility and the secondary circulation facility as a function of a temperature of the dielectric fluid in the tank, wherein the control facility is configured to maintain the temperature of the dielectric fluid within a maximum temperature based on at least a flow rate of the primary circulation facility, a flow rate of the secondary circulation facility, and a temperature of a cooling fluid of the secondary circulation facility.

12. An immersion cooling system comprising:
a tank comprising a plurality of appliance slots, the tank configured to hold a dielectric fluid and a plurality of electrical appliances immersed in the dielectric fluid, each of the plurality of electrical appliances corresponding to a respective appliance slot of the plurality of appliance slots;
a fluid recovery reservoir configured to receive the dielectric fluid flowing from an overflow structure, wherein the overflow structure is configured to facilitate substantially uniform recovery of the dielectric fluid from each of the plurality of appliance slots; and
a primary circulation facility comprising:
a plenum positioned adjacent to a bottom of the plurality of electrical appliances and configured to facilitate a flow of the dielectric fluid into each of the plurality of appliance slots;
a first primary circulation sub-facility comprising a first primary circulation pump configured to pump the dielectric fluid from the fluid recovery reservoir to the plenum; and
a second primary circulation sub-facility comprising a second primary circulation pump configured to pump the dielectric fluid from the fluid recovery reservoir to the plenum, wherein the second primary circulation sub-facility is a redundant component of the first primary circulation sub-facility.

13. The immersion cooling system of claim 12, wherein the first primary circulation sub-facility further comprises a first heat exchanger and the second primary circulation sub-facility further comprises a second heat exchanger, each of the first heat exchanger and the second heat exchanger configured to extract heat from the dielectric fluid prior to the dielectric fluid being returned to the plenum.

14. The immersion cooling system of claim 12, further comprising a control facility configured to:
coordinate operation of the first primary circulation sub-facility and the second primary circulation sub-facility; and
maintain a temperature of the dielectric fluid in the tank within a predetermined temperature range by selectively activating one or both of the first primary circulation sub-facility and the second primary circulation sub-facility.

15. The immersion cooling system of claim 14, wherein the control facility is further configured to operate the first primary circulation sub-facility and the second primary circulation sub-facility simultaneously in response to the temperature of the dielectric fluid in the tank rising above a predetermined maximum temperature.

16. The immersion cooling system of claim 12, further comprising:
a secondary circulation facility comprising a cooling tower and a secondary circulation pump, wherein the secondary circulation pump is configured to extract heat from the dielectric fluid flowing through a heat exchanger of the cooling tower and dissipate the extracted heat to the environment; and
a control facility is configured to coordinate operation of the secondary circulation facility.

17. The immersion cooling system of claim 16, wherein the control facility is further configured to facilitate remote monitoring and adjustment of operating parameters of the immersion cooling system via a communication network.

18. A method of cooling electrical appliances immersed in dielectric fluid of an immersion cooling system, the method comprising:
circulating, by one or more circulation pumps, the dielectric fluid from a plenum positioned adjacent to a bottom of a tank into each of a plurality of appliance slots of the tank, wherein the plurality of appliance slots are configured to hold a plurality of electrical appliances;
providing, by the plenum, a flow of the dielectric fluid through each of the plurality of appliance slots to extract heat from the plurality of electrical appliances;
recovering, by a fluid recovery reservoir, the flow of the dielectric fluid from an overflow structure of a weir, wherein the fluid recovery reservoir is positioned beneath the overflow structure of the weir, and wherein the weir is configured to facilitate substantially uniform recovery of the dielectric fluid from each of the plurality of appliance slots;
transferring, by a heat exchanger of a primary circulation facility, the heat from the dielectric fluid to a cooling fluid to produce cooled dielectric fluid; and
returning, by the one or more circulation pumps, the cooled dielectric fluid from the primary circulation facility to the plenum.

19. The method of claim 18, further comprising:
monitoring, by a control facility, a temperature of the dielectric fluid in the tank using at least one temperature sensor; and
adjusting, by the control facility, operation of the one or more circulation pumps based on the monitored temperature of the dielectric fluid.

20. The method of claim 18, further comprising:
blocking, by one or more flow barriers, the flow of the dielectric fluid through a portion of the plenum corresponding to one or more unoccupied appliance slots of the plurality of appliance slots.

21. An immersion cooling system comprising:
a tank comprising a plurality of appliance slots, the tank configured to hold a dielectric fluid and a plurality of electrical appliances immersed in the dielectric fluid, each of the plurality of electrical appliances corresponding to a respective appliance slot of the plurality of appliance slots;
a fluid recovery reservoir configured to receive the dielectric fluid flowing from an overflow structure; and
a primary circulation facility comprising:
a plenum positioned adjacent to a bottom of the tank, wherein the plenum is configured to facilitate a substantially equal flow rate of the dielectric fluid into each of the plurality of appliance slots;
a first primary circulation sub-facility comprising a first primary circulation pump configured to pump the dielectric fluid from the fluid recovery reservoir to the plenum; and
a second primary circulation sub-facility comprising a second primary circulation pump configured to pump the dielectric fluid from the fluid recovery reservoir to the plenum, wherein the second primary circulation sub-facility is a redundant component of the first primary circulation sub-facility.
